(19) United States
(12) Patent Application Publication
(10) Pub. No.: US 2025/0309157 A1
(43) Pub. Date: Oct. 2, 2025

(54) SEMICONDUCTOR DEVICES AND METHODS OF MANUFACTURING SEMICONDUCTOR DEVICES

(71) Applicant: Amkor Technology Singapore Holding Pte. Ltd., Singapore (SG)

(72) Inventors: Sang Hyun Jin, Incheon (KR); Tae Kyeong Hwang, Seoul (KR); Won Chul Do, Seoul (KR)

(73) Assignee: Amkor Technology Singapore Holding Pte. Ltd., Singapore (SG)

(21) Appl. No.: 18/617,558

(22) Filed: Mar. 26, 2024

(51) Int. Cl. H01L 23/00; H01L 21/48; H01L 23/498; H01L 23/538

(52) U.S. Cl. CPC H01L 24/02; H01L 21/4857; H01L 23/49822; H01L 23/49894; H01L 23/5383; H01L 24/20; H01L 24/32; H01L 24/33; H01L 24/03; H01L 24/05; H01L 24/11; H01L 24/13; H01L 24/16; H01L 24/73; H01L 2224/02313; H01L 2224/0239; H01L 2224/024; H01L 2224/03912; H01L 2224/05558; H01L 2224/05569; H01L 2224/05573; H01L 2224/11849; H01L 2224/13082; H01L 2224/13111; H01L 2224/13113; H01L 2224/13116; H01L 2224/13139; H01L 2224/13144; H01L 2224/13147; H01L 2224/13155; H01L 2224/13164; H01L 2224/16227; H01L 2224/211; H01L 2224/215; H01L 2224/32225; H01L 2224/32245; H01L 2224/33181; H01L 2224/73204; H01L 2224/73253; H01L 2924/01022; H01L 2924/01028; H01L 2924/01029; H01L 2924/01046; H01L 2924/01047; H01L 2924/01073; H01L 2924/01074; H01L 2924/01079; H01L 2924/01081; H01L 2924/0132; H01L 2924/0133; H01L 2924/014; H01L 2924/04941; H01L 2924/066; H01L 2924/07025

(57) ABSTRACT

In one example, an electronic device can comprise a substrate, a first passivation structure over the substrate and defining a first opening, and a first conductive pattern formed in the first opening. A second passivation structure can be disposed over the first conductive pattern and the first passivation structure. The second passivation structure can include a high-resolution material and a high-function material. The high-resolution material of the second passivation structure can define a second opening. A second conductive pattern can be disposed in the second opening of the second passivation structure. The high-function material can be disposed between the first conductive pattern and the second conductive pattern. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic component.

FIGS. 2A to 2T show an example method for manufacturing an example electronic component using cross-sectional views.

FIG. 3 shows a cross-sectional view of an example electronic component.

FIG. 4 shows a cross-sectional view of an example electronic device.

FIG. 5 shows a cross-sectional view of an example electronic device.

FIG. 6 shows a cross-sectional view of an example electronic device.

FIG. 7 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements; however, the elements described using “first,” “second,” etc. are not to be limited by these terms. The terms “first,” “second,” etc. are only used to distinguish one element from another. For example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term coupled can refer to an electrical coupling or a mechanical coupling.

### DESCRIPTION

An example electronic device can comprise a substrate, a first passivation structure over the substrate and defining a first opening, and a first conductive pattern formed in the first opening. A second passivation structure can be disposed over the first conductive pattern and the first passivation structure. The second passivation structure can include a high-resolution material and a high-function material. The high-resolution material of the second passivation structure can define a second opening. A second conductive pattern can be disposed in the second opening of the second passivation structure. The high-function material can be disposed between the first conductive pattern and the second conductive pattern.

In various examples, the high-function material defines a first via extending through the second passivation structure to the first conductive pattern. The high-resolution material can define a second via extending through the first via of the second passivation structure to the first conductive pattern. A seed layer can extend through the first via and the second via to the first conductive pattern. The high-resolution material can be between the high-function material and the seed layer. The high-function material can include a dielectric constant (Dk) less than 3.0. The high-function material can include a dissipation factor (Df) less than 0.004. The high-resolution material can comprise a material capable of patterning at a resolution value less than 2 micrometers. The high-function material can comprise a first organic and the high-resolution material can comprise a second organic.

In some examples, the substrate comprises an electronic component and an encapsulant disposed around lateral sides of the electronic component. A thermal adhesive can be coupled to a top side of the electronic component, and a heat spreader can be coupled to the thermal adhesive. A redistribution layer (RDL) substrate can be electrically coupled to the electronic component through the first conductive pattern and the second conductive pattern. The heat spreader can be coupled to the RDL substrate. An underfill can be between the electronic component and the first passivation structure. The high-functional material can include a positive-type photo-sensitive polyimide (PSPI).

Another example electronic device can include a substrate, a first dielectric material over the substrate and defining a first opening, and a first conductive pattern formed in the first opening. A second dielectric material can be disposed over the first conductive pattern and the first dielectric material. The second dielectric material comprises a high-function material that defines a second opening. A third dielectric material can be disposed over the second dielectric material and can extend into the second opening. The third dielectric material can include a high-resolution material that defines a third opening. A second conductive pattern can be disposed in the third opening of the high-resolution material. The high-function material can be between the first conductive pattern and the second conductive pattern.

An example method of manufacturing a semiconductor device includes the steps of providing a substrate, providing a first dielectric material over the substrate, wherein the first dielectric material defines a first opening, and providing a first conductive pattern in the first opening. A second dielectric material can be provided over the first conductive pattern and the first dielectric material. The second dielectric material can include a high-function material and defines a second opening. A third dielectric material can be provided over the second dielectric material and extending into the second opening. The third dielectric material can include a high-resolution material and defines a third opening. The example method can also include providing a second conductive pattern disposed in the third opening of the third dielectric material. The high-function material can be disposed between the first conductive pattern and the second conductive pattern.

Other examples are included in the present disclosure. Such examples may be found in the figures, in the claims, or in the description of the present disclosure.

Devices and methods of the present disclosure tend to inhibit signal noise and electron migration between adjacent conductive components of electronic devices. Embedded traces can be formed with a heterogeneous passivation structure. The heterogeneous passivation structure can enable formation of high-resolution traces with a high-resolution insulating material (e.g., high-resolution polyimide). The heterogeneous passivation structure can also impede unwanted electromagnetic communication between adjacent traces with a high-function insulating material (e.g., high-function polyimide). The high-function insulating material and high-resolution insulating material can be interleaved, layered, selectively placed, or otherwise structured to increase reliability and electrical performance of traces (e.g., in embedded trace redistribution layers).

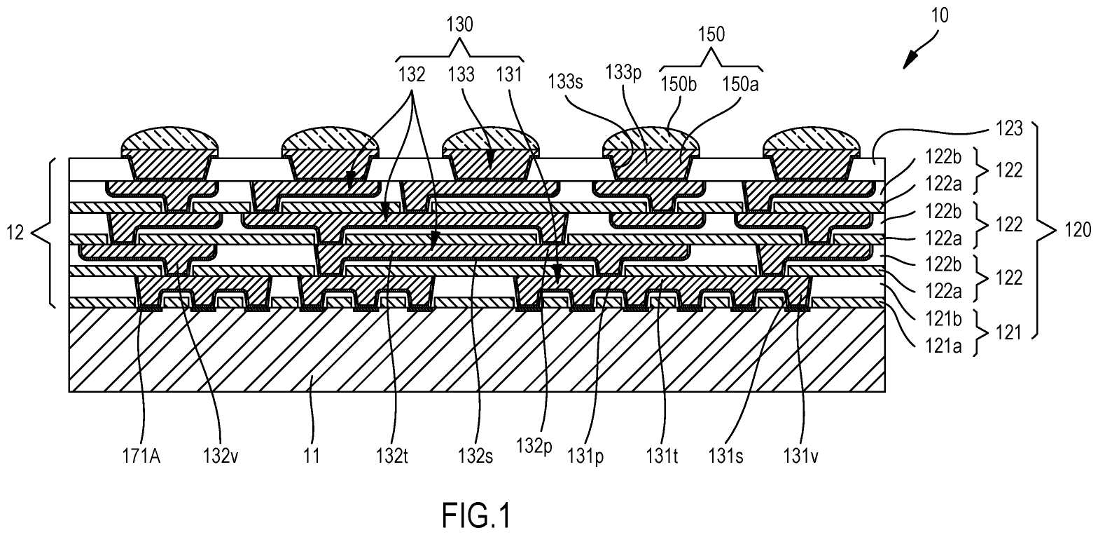

FIG. 1 shows a cross-sectional view of an example electronic component 10. In the example shown in FIG. 1, electronic component 10 can comprise substrate 11 and build-up redistribution layer (RDL) 12. Build-up RDL 12 can comprise dielectric structure 120, conductive structure 130, and device interconnects 150.

Dielectric structure 120 can comprise first (or inner) passivation structure 121, one or more second (or intermediate) passivation structure(s) 122, and outer passivation structure 123. First passivation structure 121 can comprise first dielectric material 121a and second dielectric material 121b. Each second passivation structure 122 can comprise first dielectric material 122a and second dielectric material 122b.

Conductive structure 130 can comprise first conductive pattern 131, one or more second conductive pattern(s) 132, and outer conductive pattern 133. First conductive pattern 131 can comprise seed layer 131s, traces 131t, pads 131p, and vias 131v. Each second conductive pattern 132 can comprise seed layer 132s, traces 132t, pads 132p, and vias 132v. Outer conductive pattern 133 can comprise seed layer 133s and pads 133p.

Second passivation structures 122 and second conductive patterns 132 can be built-up by repetition, thereby forming build-up RDL 12. Build-up RDL 12, including dielectric structure 120, conductive structure 130, and device interconnects 150, can be referred to as a semiconductor package. In some examples, the semiconductor package can protect substrate 11 from external elements or environmental exposure. In some examples, the semiconductor package can electrically couple external electrical components and substrate 11.

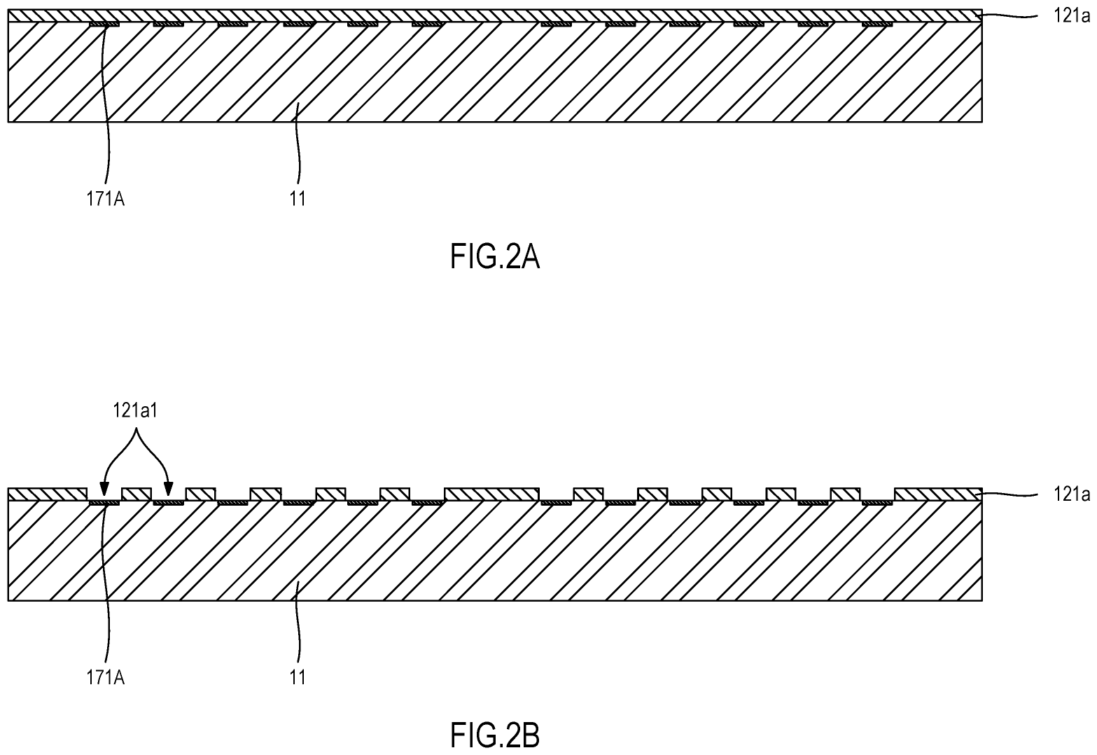

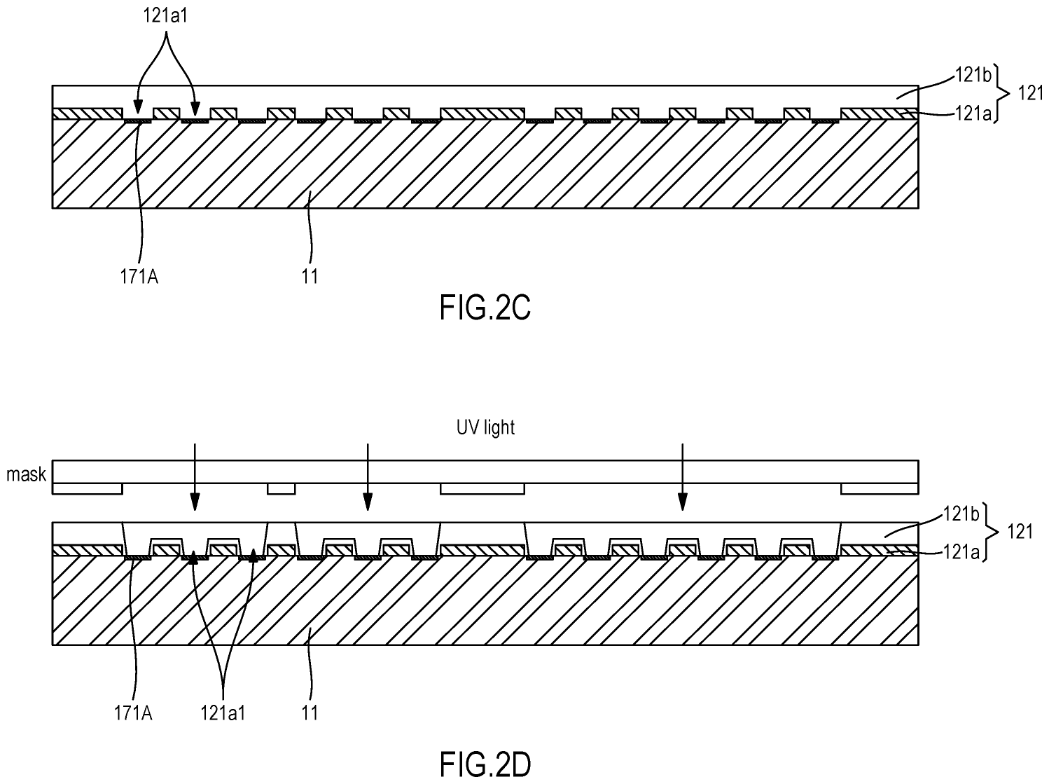

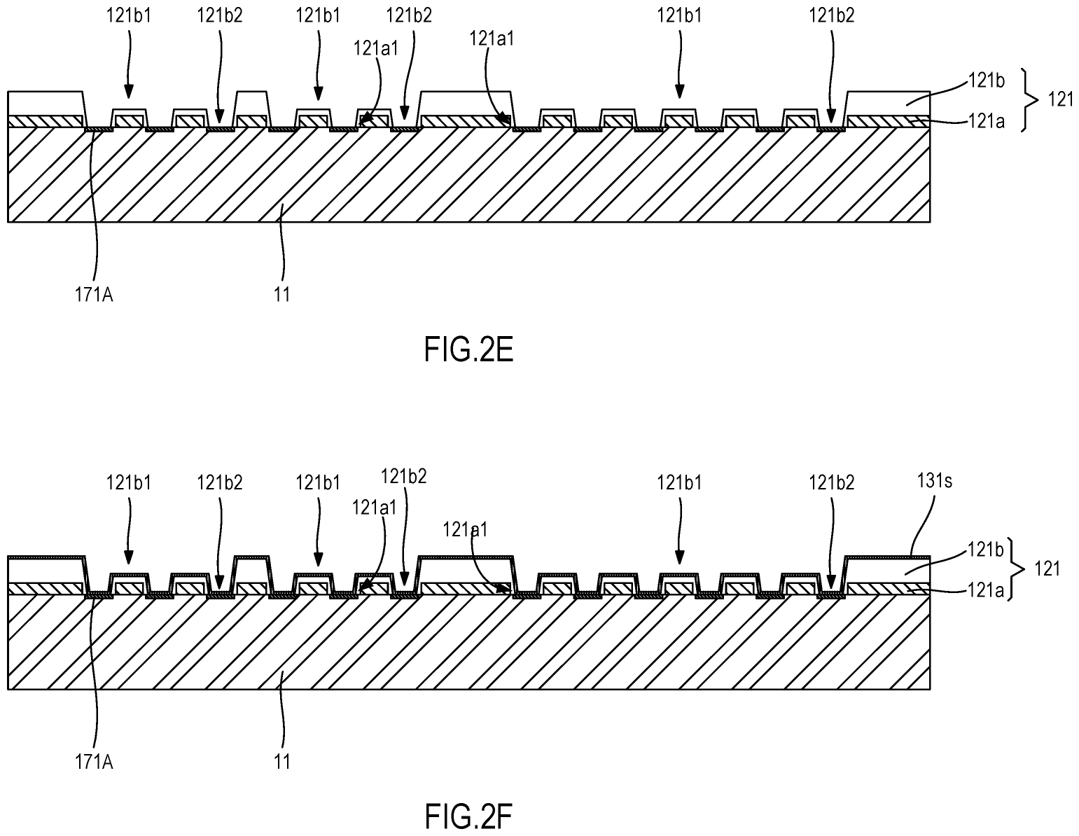

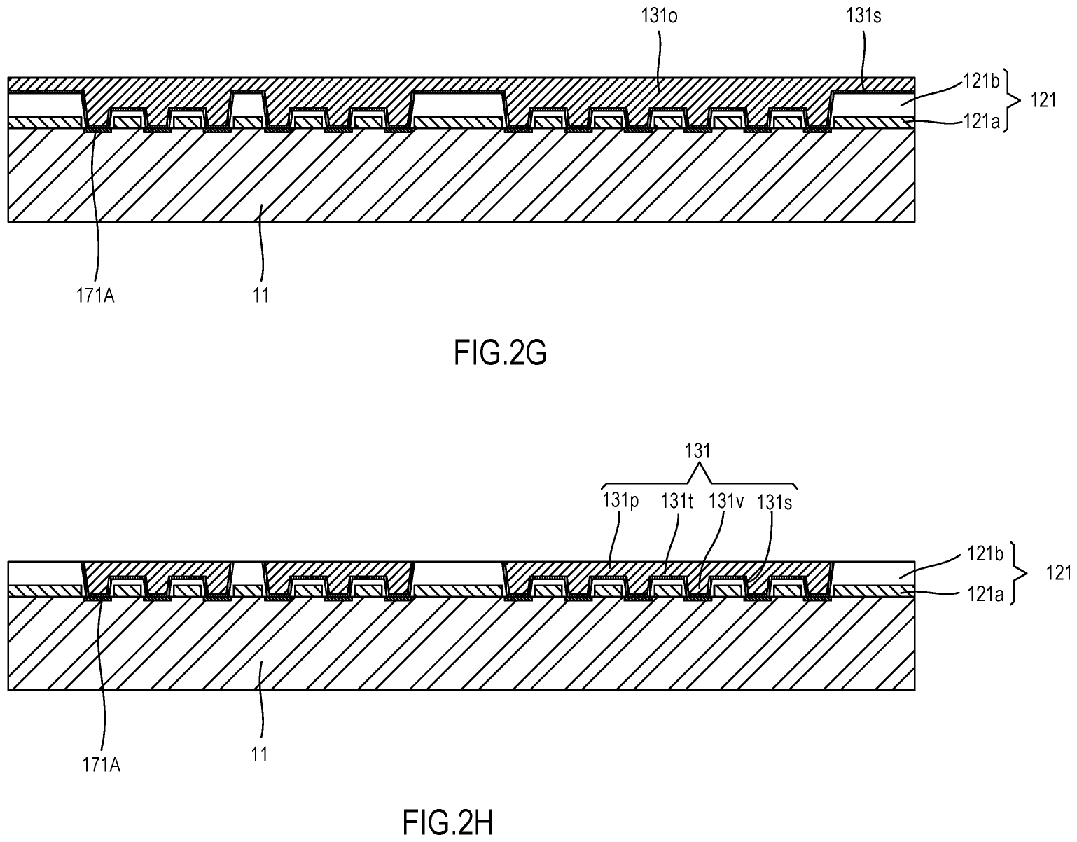

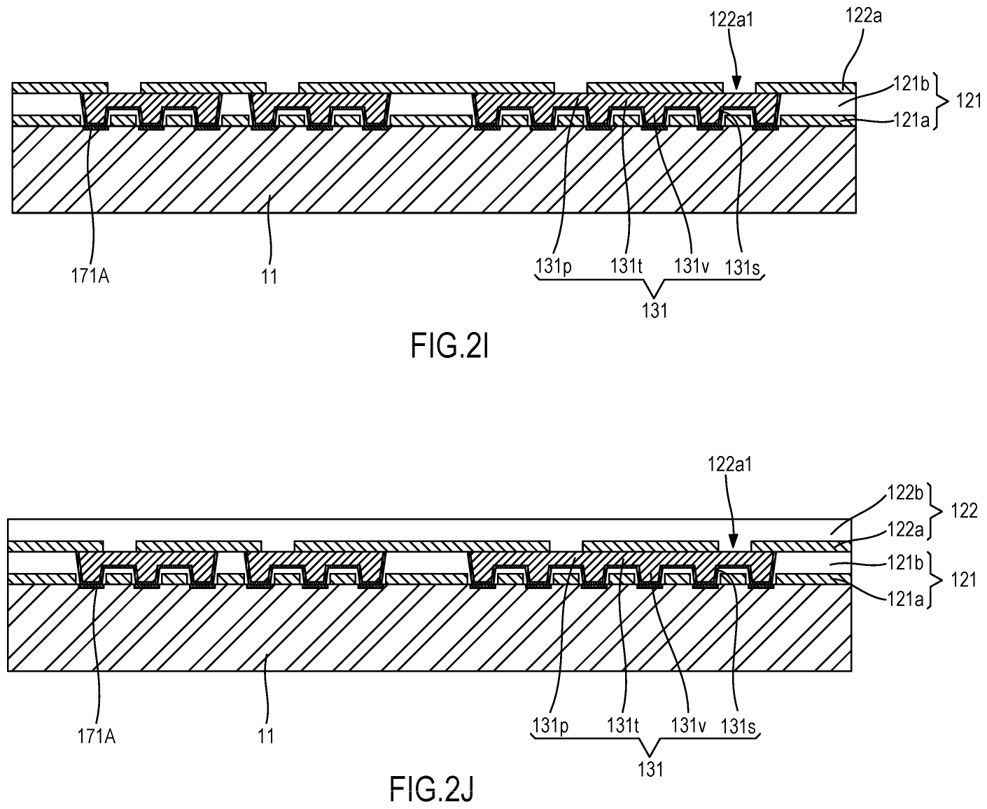

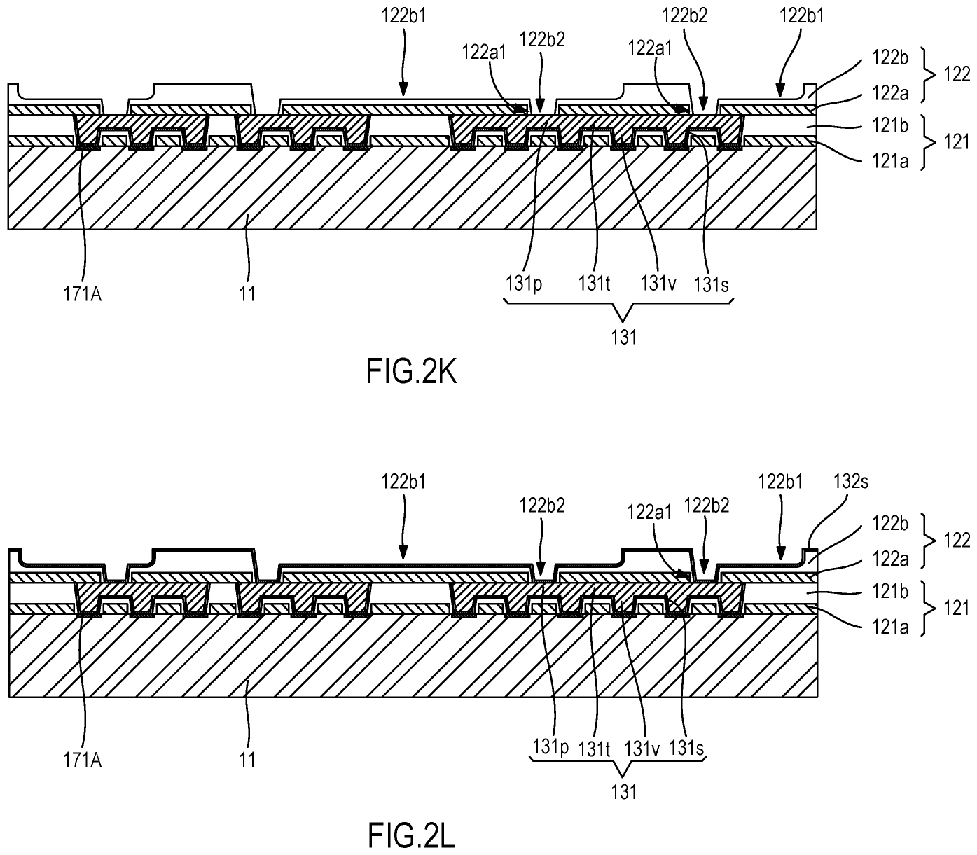

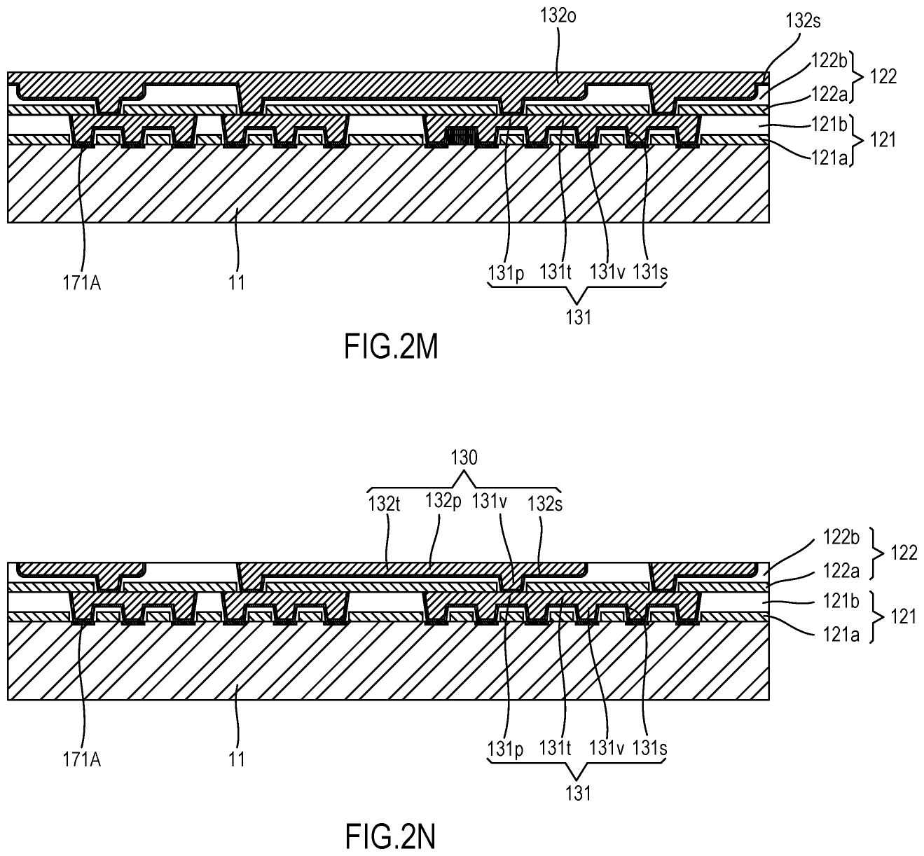

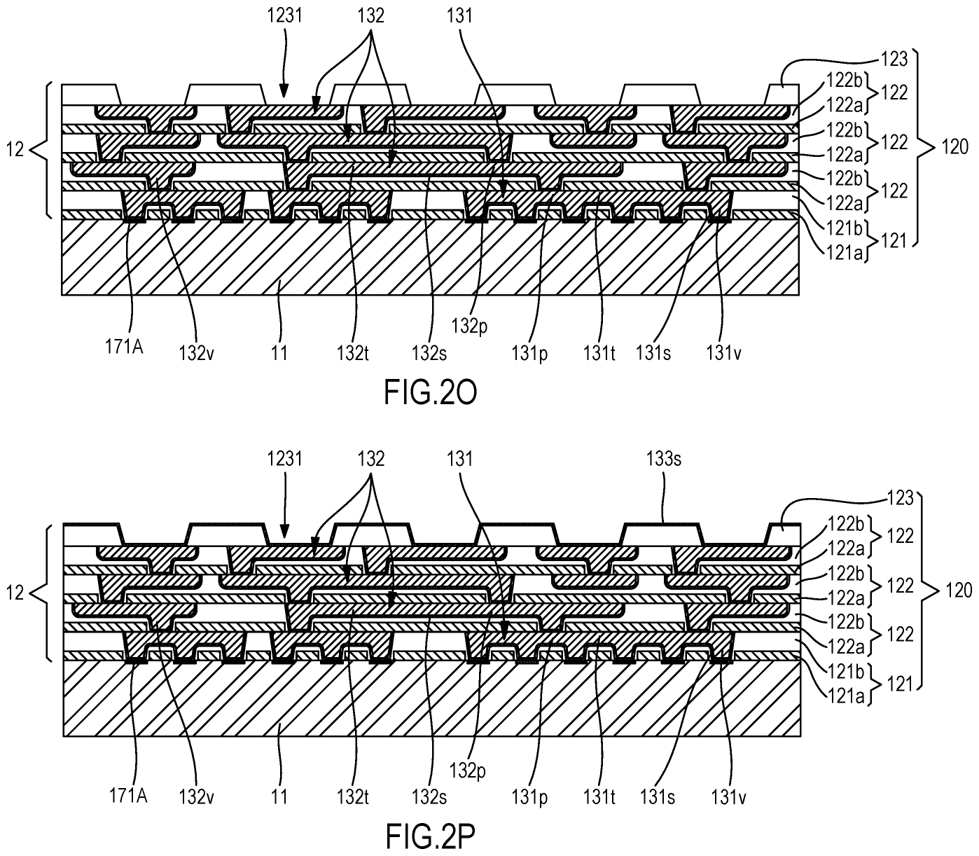

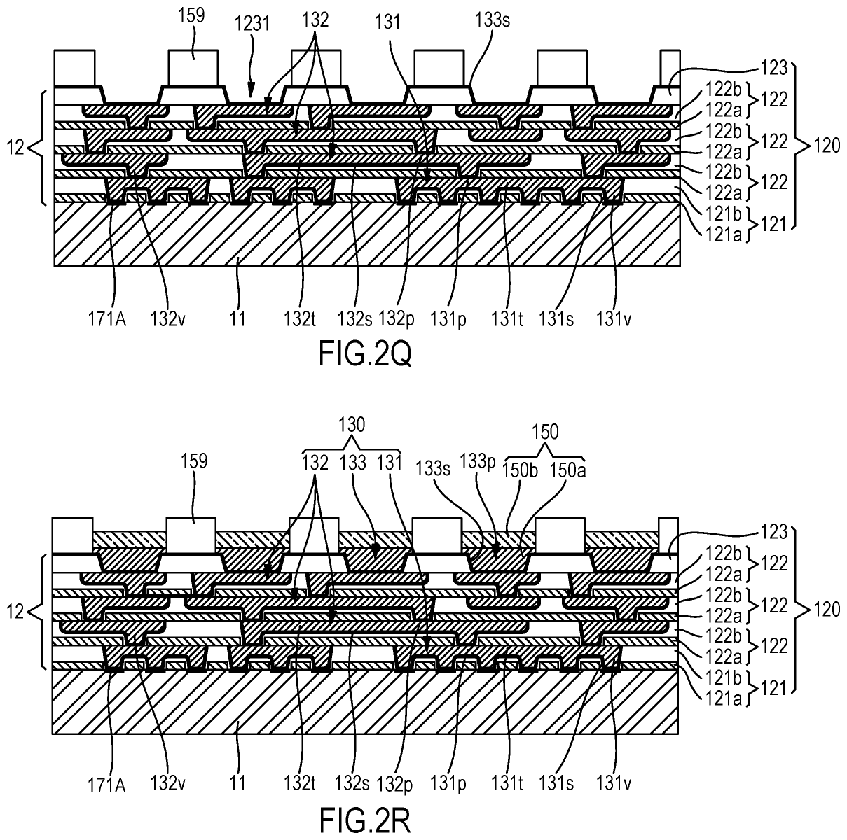

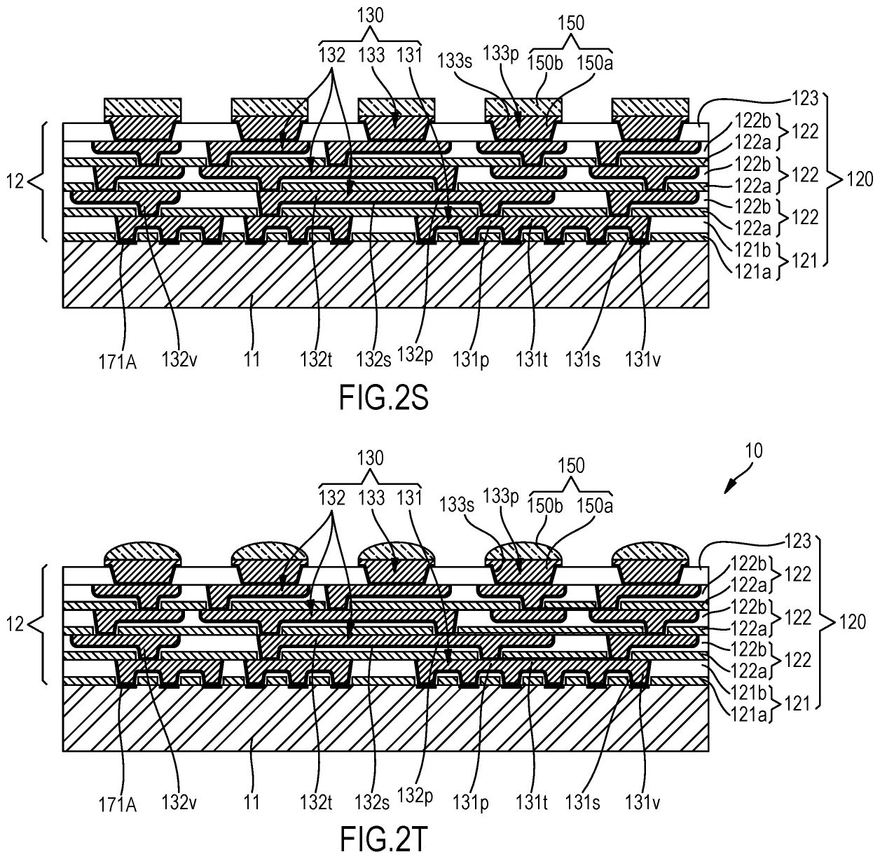

FIGS. 2A to 2T show cross-sectional views of an example method for manufacturing electronic component 10. FIG. 2A shows a cross-sectional view of electronic component 10 at an early stage of manufacture.

In the example shown in FIG. 2A, first dielectric material 121a can be provided on substrate 11. In some examples, substrate 11 can comprise or be referred to as a wafer, a reconstituted wafer, or a removable carrier. For example, substrate 11 can be a wafer having a plurality of semiconductor die separated by saw streets and can be used to manufacture electronic devices comprising Wafer Level Packages (WLPs) or Wafer Level Chip Size Packages (WLCSPs). In some examples, substrate 11 can be a reconstituted wafer comprising a plurality of known good semiconductor die aggregated and reconstituted (e.g., encapsulated) to form substrate 11 (e.g., encapsulant can be located between adjacent semiconductor die). The reconstituted wafer can be used to manufacture electronic devices comprising, for example, Wafer Level Fan Out (WLFO) devices. In some examples, substrate 11 can comprise a removable (or temporary) carrier and can be used to manufacture electronic devices comprising RDL substrates or interposers (e.g., build-up RDL 12) on which electronic components (e.g., semiconductor die, passive devices, or other electronic packages) are coupled. In such examples, the removable carrier (i.e., substrate 11) can be formed of, for example, silicon, glass, ceramic, or metal, and can be removed from the RDL substrate (e.g., build-up RDL 12) after the electronic components have been attached to the RDL substrate. The thickness of substrate 11 can range from about 200 micrometers (μm) to about 1000 μm. In some examples, the thickness of substrate 11 can range from about 20 μm to about 1000 μm. As used herein with numeric values or percentages, the term “about” can mean +/−5%, +/−10%, +/−15%, +/−20%, or +/−25%.

In accordance with various examples, first dielectric material 121a can be coated or spun-on in liquid form or laminated as a pre-formed film on substrate 11. In some examples, substrate 11 can be a wafer or a reconstituted wafer, and first dielectric material 121a can be provided over component interconnects 171A of substrate 11. In some examples, first dielectric material 121a can comprise or be referred to as a photo imageable organic passivation material, PI (polyimide), BCB (benzocyclobutene), PBO (polybenzoxazole), phenolic resin, or ABF (Ajinomoto Buildup Film). In some examples, first dielectric material 121a can comprise one or more layers of high functional dielectric materials, such as high functional PI or other high reliability material. As used herein, phrases such as “high function,” “high functional,” or similar phrases can be used to refer to low-loss materials such as, for example, Asahi BL301. High functional materials can have properties such as a dielectric constant (Dk)<3.0 or a dissipation factor (Df)<0.004. The dielectric constant may represent a degree of polarization of a material. The dissipation factor may represent an energy loss by reverse polarization of a material. In some examples, first dielectric material 121a can provide high functionality. In some examples, high functionality can comprise low dielectric properties or insulation properties such as, for example, low Dk (i.e., less than about 3) or low Df (i.e., less than about 0.004). In some examples, high functionality can comprise high mechanical properties such as, for example, elongation values greater than about 40% or tensile strength values greater than about 130 Megapascals (MPa)). In some examples, high functionality can comprise high heat resistance such as, for example, 5% weight loss at temperatures greater than about 300° C. or glass transition temperature (Tg) greater than about 200° C. In some examples, high functionality can comprise high reliability or adhesion such as, for example, moisture uptake less than about 1% or adhesion greater than about 70 MPa. High functionality may also describe other desirable physical properties of dielectric material 121a.

In some examples, first dielectric material 121a can comprise a photo-sensitive polyimide (PSPI). The PSPI can be a type of polyimide material sensitive to light, allowing the PSPI to be patterned through a photolithography process. The PSPI can comprise a positive-type PSPI, negative-type PSPI, or a chemically amplified PSPI. In the positive-type PSPI, the polymer can become more soluble in the areas exposed to light, and the upper area of the opening formed after development is relatively wide. In the negative-type PSPI, the polymer can become insoluble in the areas exposed to light, and the lower area of the opening, after development, is formed to be relatively wide. A chemically amplified PSPI can use a chemical amplification process to enhance the sensitivity of the material to light. The chemically amplified PSPI can allow for improved resolution and sensitivity in patterning. The chemically amplified PSPI can be used when microfabrication processes call for fine features or high resolution. The thickness of first dielectric material 121a can range from about 3 μm to about 100 μm.

FIG. 2B shows a cross-sectional view of electronic component 10 at a later stage of manufacture. In the example shown in FIG. 2B, vias 121a1 can be provided in first dielectric material 121a. In some examples, vias 121a1 can be formed through first dielectric material 121a using a patterning process. The patterning process can comprise, for example, light exposure, development, and curing.

In some examples, a mask having a pattern corresponding to the locations of vias 121a1 can be positioned on first dielectric material 121a and exposed to ultraviolet rays, thereby transferring the pattern to first dielectric material 121a. The portion of first dielectric material 121a that includes the transferred pattern (or, in some examples, the portion that does not include the transferred pattern) is then developed and cured, leaving vias 121a1 patterned in first dielectric material 121a. Portions of substrate 11 can be exposed through vias 121a1. In some examples, substrate 11 can include component interconnect 171A and vias 121a1 can be located over and can expose component interconnects 171A.

FIG. 2C shows a cross-sectional view of electronic component 10 at a later stage of manufacture. In the example shown in FIG. 2C, second dielectric material 121b can be provided on first dielectric material 121a and substrate 11. Second dielectric material 121b can cover or fill vias 121a1 in first dielectric material 121a. Second dielectric material 121b can be coated or spun-on in liquid form or laminated as a pre-formed film on first dielectric material 121a and substrate 11. In some examples, second dielectric material 121b can be similar to first dielectric material 121a. In some examples, second dielectric material 121b can comprise one or more layers of high-resolution dielectric materials, such as high-resolution PI (e.g., a high-resolution material having resolution capable of patterning at resolution values less than or equal to about 2 μm). Higher resolution materials described herein refer to patterning at lower resolution values (e.g., a resolution value of 2 μm indicates a higher resolution material than a resolution value of 3 μm, but the resolution value 2 μm is less than the resolution value 3 μm).

In some examples, second dielectric material 121b can comprise a positive-type chemically amplified PSPI or a negative-type chemically amplified PSPI. The thickness of second dielectric material 121b can range from about 3 μm to about 100 μm. The second dielectric material 121b can have a resolution of approximately 2 μm. Second dielectric material 121b can support first conductive pattern 131 to be provided in a later process. In some examples, second dielectric material 121b can comprise a high-resolution material. The high-resolution material can lack characteristics of the high-function material in some examples. In some examples, the solubility of second dielectric material 121b in the developer is higher than the solubility of first dielectric material 121a in the developer, so the pattern resolution of second dielectric material 121b can be higher than the pattern resolution of first dielectric material 121a.

FIG. 2D shows a cross-sectional view of electronic component 10 at a later stage of manufacture. In the example shown in FIG. 2D, second dielectric material 121b can be exposed by UV rays. In some examples, a mask with a pattern can be positioned on second dielectric material 121b and UV rays can be masked, thereby selectively forming a pattern in second dielectric material 121b. In some examples, in the case of positive-type PSPI, the portion exposed to light can undergo a chemical reaction, weakening the polymer bond. In some examples, in the case of negative-type PSPI, the portion exposed to light can undergo a chemical reaction, thereby strengthening the polymer bond. For reference, the light passing through the mask may spread due to diffraction, and the resulting chemical reaction can spread to surrounding areas other than the part receiving light due to the catalyst inside the PSPI. Therefore, the chemical reaction can occur around the area receiving light in some examples. The profile of the resulting pattern can include sloped or angled walls relative to the surface of substrate 11. Additionally, because light can be received from the top, in the case of positive type-PSPI, the chemical bond can become weak around the top of the light-receiving part, and in the case of negative-type PSPI, the chemical bond can become stronger around the top of the light-receiving part. In the case of positive type PSPI, a profile where the upper portion is additionally developed can be provided. In the case of negative-type PSPI, a profile where the upper portion is developed judiciously or developed minimally can be provided. In the example of FIG. 2D, light can be provided on a positive-type PSPI.

FIG. 2E shows a cross-sectional view of electronic component 10 at a later stage of manufacture. In the example shown in FIG. 2E, RDL patterns 121b1 and vias 121b2 are provided in second dielectric material 121b. In accordance with various examples, second dielectric material 121b can be patterned to form openings (e.g., RDL patterns 121b1 and vias 121b2) in second dielectric material 121b. In some examples, second dielectric material 121b can be patterned in a manner similar to or the same as a dual damascene process. The patterning process can comprise develop and cure process. Vias 121b2 can extend through vias 122a1 in first dielectric material 121a.

In some examples, a transferred portion or a non-transferred portion of second dielectric material 121b can be developed and cured, and second dielectric material 121b can comprise the pattern. In this way, a plurality of RDL patterns 121b1 and vias 121b2 can be formed in or through second dielectric material 121b. A portion of substrate 11 (e.g., component interconnects 171A) can be exposed through vias 121b2. In some examples, the dual damascene patterning process can be performed by repeating the process multiple times. Due to the dual damascene patterning process, the depth of vias 121b2 can be greater than the depth of RDL patterns 121b1, and the portion of substrate 11 can be exposed through via 121b2. In some examples, the portion of substrate 11 corresponding to via 121b2 can comprise component interconnect 171A. Component interconnect 171A can comprise a pad, land, UBM (Under Bump Metal), stud, bump or pillar.

In some examples including positive-type PSPI, the lower part of the PI may be unexposed to light, so the lower area of the PI can remain as is in the development process. In some examples including negative-type PSPI, even if the lower part of the PI remains unexposed, the upper PI can prevent development, so development can be done neatly to the lower part of the PI. In some examples, a denser pattern can be provided using negative-type PSPI compared to positive-type PSPI.

In some examples, first passivation structure 121 including first dielectric material 121a and second dielectric material 121b can be formed as described above. First dielectric material 121a can comprise high functional PI and second dielectric material 121b can comprise high resolution PI. First dielectric material 121a can be disposed around a portion of second dielectric material 121b with via 121b2 extending through both first dielectric material 121a and second dielectric material 121b.

FIG. 2F shows a cross-sectional view of electronic component 10 at a later stage of manufacture. In the example shown in FIG. 2F, seed layer 131s of first conductive pattern 131 is provided on first passivation structure 121. First passivation structure 121 can support first conductive pattern 131. In some examples, seed layer 131s can be provided on RDL patterns 121b1 and vias 121b2 of second dielectric material 121b. Seed layer 131s can also be provided on the portion of substrate 11 exposed through vias 121b2. In some examples, seed layer 131s on first passivation structure 121 and substrate 11 can be electrically shorted in the entire area. In some examples, seed layer 131s can comprise Ti/Cu (Titanium/Copper), Ta/Cu (Thallium/Copper), TiW/Cu (Titanium Tungsten/Copper), or Ti/TiN/Cu (Titanium/Titanium Nitride/Copper). In some examples, a barrier metal such as Ti, Ta, TiW or TIN can first be provided on first passivation structure 121 since Cu (Copper) tends to diffuse into second dielectric material 121b. Then, Cu can be provided on the barrier metal. The barrier metal including Ti, Ta, TiW or TiN can be provided through ALD (Atomic Layer Deposition), PVD (Physical Vapor Deposition), CVD (Chemical Vapor Deposition), LPCVD (Low Pressure Chemical Vapor Deposition), or PECVD (Plasma Enhanced Chemical Vapor Deposition). Seed layer 131s including Cu can be provided through PVD, ALD, CVD, LPCVD, or PECVD. In some examples, the thickness of seed layer 131s can range from about 0.05 μm to about 1 μm. Seed layer 131s can provide a current supply path for electroplating conductive structure 130 (e.g., first conductive pattern 1310 in FIG. 2G).

FIG. 2G shows a cross-sectional view of electronic component 10 at a later stage of manufacture. In the example shown in FIG. 2G, first conductive pattern 1310 can be provided on seed layer 131s. In some examples, first conductive pattern 1310 can be provided over substrate 11 and first passivation structure 121 including RDL patterns and vias. In some examples, first conductive pattern 1310 can comprise or be referred to as an electrodeposition layer or an electrode plating layer. In some examples, first conductive pattern 1310 can comprise Cu (Copper), Ni (Nickel), Pd (Palladium), Ag (Silver), or Au (Gold). In some examples, first conductive pattern 1310 can be provided by electrodeposition on seed layer 131s. In some examples, electrodeposition can be a method to produce in situ metallic coatings by the action of an electric current on a conductive material immersed in a solution containing a salt of the metal to be deposited. The thickness of first conductive pattern 1310 can be provided thicker than the thickness of the RDL patterns and vias in first passivation structure 121. In some examples, the thickness of first conductive pattern 1310 can range from about 3 μm to about 200 μm.

FIG. 2H shows a cross-sectional view of electronic component 10 at a later stage of manufacture. In the example shown in FIG. 2H, a top side of first conductive pattern 1310 can be planarized. In some examples, a chemical mechanical polishing pad can grind the top side of first conductive pattern 1310. Chemical mechanical polishing can be performed until the top side of first passivation structure 121 (e.g., second dielectric material 121b) is exposed. In some examples, a portion of seed layer 131s on the top side of first passivation structure 121 can also be ground and removed. In some examples, after the chemical mechanical polishing process, the top side of first conductive pattern 1310 and top side of first passivation structure 121 can be coplanar. In some examples, portions of first conductive patterns 131 can be electrically and mechanically isolated from each other. First conductive pattern 131 with RDL patterns including traces 131t and pads 131p and conductive vias including vias 131v can be provided on first passivation structure 121. In some examples, via 131v corresponding to component interconnect 171A of substrate 11 can comprise an inward terminal. In some examples, first conductive pattern 131 can comprise or be referred to as traces, pads, conductive paths, or conductive vias. In some examples, the thickness of first conductive pattern 131 can range from about 3 μm to about 100 μm. First conductive pattern 131 can provide horizontal and vertical current paths between electronic component 10 and an external device.

FIG. 2I shows a cross-sectional view of electronic component 10 at a later stage of manufacture. In the example shown in FIG. 2I, first dielectric material 122a is provided on first conductive pattern 131 and first passivation structure 121. The process shown in FIG. 2I can be similar to or the same as the process shown in FIGS. 2A and 2B. In some examples, first dielectric material 122a can comprise or be referred to as a photo imageable organic passivation material, PI, BCB, PBO, phenolic resin, or ABF. In some examples, first dielectric material 122a can comprise one or more layers of high functional dielectric materials, such as high functional PSPI or other high reliability material. Such high functional PSPI can be coated or spun-on in liquid form or attached as a pre-formed film on first conductive pattern 131 and first passivation structure 121. In accordance with various examples, vias 122a1 can be provided in first dielectric material 122a. For example, first dielectric material 122a can be patterned to form vias 122a1. The patterning process can comprise a coating or laminating, exposure, develop, and cure process. In this way, first dielectric material 122a including vias 122a1 can be formed and can support second conductive pattern 132, as described in further detail below.

FIG. 2J shows a cross-sectional view of electronic component 10 at a later stage of manufacture. In the example shown in FIG. 2J, second dielectric material 122b can be provided on first dielectric material 122a and first conductive pattern 131. The process shown in FIG. 2J can be similar to or the same as the process shown in FIG. 2C. Second dielectric material 122b can cover or fill vias 122a1 of first dielectric material 122a. Second dielectric material 122b can be coated or spun-on in liquid form or laminated as a pre-formed film on first dielectric material 122a and first conductive pattern 131. In some examples, second dielectric material 122b can be similar to second dielectric material 121b. In some examples, second dielectric material 122b can comprise one or more layers of high-resolution dielectric materials, such as high-resolution PI (e.g., high resolution required less than 2 μm). In some examples, second dielectric material 122b can comprise a positive-type chemically amplified PSPI or a negative-type chemically amplified PSPI. In some examples, second dielectric material 122b can be selected for higher-resolution and first dielectric material 122a can be selected for high-functionality.

FIG. 2K shows a cross-sectional view of electronic component 10 at a later stage of manufacture. In the example shown in FIG. 2K, second dielectric material 122b is patterned. In some examples, second dielectric material 122b can be patterned in a manner similar to or the same as a dual damascene process. In some examples, RDL patterns 122b1 and vias 122b2 can be provided in second dielectric material 122b by a patterning process. The process shown in FIG. 2K can be similar to or the same as the process shown in FIGS. 2D and 2E. Through the patterning process, a portion of first conductive pattern 131 (e.g., pads 131p) can be exposed through vias 122b2 and through vias 122a1.

In some examples, second passivation structure 122 including first dielectric material 122a and second dielectric material 122b can be formed in this way. First dielectric material 122a can comprise high-functional PI, and second dielectric material 122b can comprise high-resolution PI. Second passivation structure 122 can support a second conductive pattern, as described in further detail below.

FIG. 2L shows a cross-sectional view of electronic component 10 at a later stage of manufacture. In the example shown in FIG. 2L, seed layer 132s is provided on second dielectric material 122b and first conductive pattern 131 (e.g., pads 131p). In some examples, seed layer 132s can cover an exposed portion of first conductive pattern 131 (e.g., pads 131p). In some examples, the top side of first conductive pattern 131 (e.g., pads 131p) can be covered with and contacted by seed layer 132s. The process shown in FIG. 2L can be similar to or the same as the process shown in FIG. 2F.

FIG. 2M shows a cross-sectional view of electronic component 10 at a later stage of manufacture. In the example shown in FIG. 2M, second conductive pattern 1320 is provided on seed layer 132s. In some examples, second conductive pattern 1320 can be provided over second dielectric material 122b including RDL patterns 122b1 and vias 122b2. In some examples, second conductive pattern 1320 can comprise or be referred to as an electrodeposition layer or an electrode plating layer. In some examples, second conductive pattern 1320 can comprise Cu, Ni, Pd, Ag, or Au. The process shown in FIG. 2M can be similar to of the same as the process shown in FIG. 2H.

FIG. 2N shows a cross-sectional view of electronic component 10 at a later stage of manufacture. In the example shown in FIG. 2N, a top side of second conductive pattern 1320 can be planarized. In some examples, a chemical mechanical polishing pad can grind the top side of second conductive pattern 1320. Chemical mechanical polishing can be performed until the top side of second dielectric material 122b is exposed. In some examples, a portion of seed layer 132s on the top side of second dielectric material 122b can also be ground and removed. In some examples, after the chemical mechanical polishing process, the top side of second conductive pattern 1320 and top side of second dielectric material 122b can be coplanar. In some examples, in response to the chemical mechanical polishing process, portions of second conductive pattern 132 can be electrically and mechanically isolated from each other. Second conductive pattern 132 with RDL patterns including traces 132t and pads 132p and conductive vias including vias 132v can be provided on second passivation structure 122. In some examples, second conductive pattern 132 can be coupled to first conductive pattern 131 through vias 132v. The process shown in FIG. 2N can be similar to or the same as the process shown in FIG. 2H.

FIG. 2O shows cross-sectional views of electronic component 10 at a later stage of manufacture. In the example shown in FIG. 2O, a process similar to the fabrication process shown in FIGS. 2I-2N can be repeated multiple times to provide multiple second passivation structures 122, each including first dielectric material 122a and second dielectric material 122b, and multiple second conductive patterns 132, each including seed layer 132s, pads 132p, traces 132t, and vias 132v. Accordingly, dielectric structure 120 can include first passivation structure 121 and any number of second passivation structures 122, and conductive structure 130 can include first conductive pattern 131 and any number of second conductive patterns 132. In accordance with various examples, second conductive patterns 132 can be formed on or in high resolution second dielectric material 122b, and high function first dielectric material 122a can be located above and below second conductive patterns 132 (e.g., below pads 132p and above and below traces 132t). For example, high function first dielectric material 122a can be located vertically between adjacent second conductive patterns 132. High resolution second dielectric material 122b can allow for formation narrow or fine pitch traces and vias, while high function first dielectric material 122a inhibits or prevents electrical noise, oxidation, and ion migration between the adjacent conductive elements.

In accordance with various examples, an outer passivation structure 123 can be formed over the last (or top) second passivation structure 122 and the last (or top) second conductive pattern 132. In some examples, outer passivation structure 123 can comprise one or more layers of dielectric material such as PI, BCB, PBO, resin or solder resist. A plurality of openings 1231 can be provided in outer passivation structure 123. A portion of second conductive pattern 132 (e.g., pads 132p) can be exposed through openings 1231 in outer passivation structure 123. The process of forming openings 1231 can be similar to or the same as the process shown in FIGS. 2B and 2I.

FIG. 2P shows cross-sectional views of electronic component 10 at a later stage of manufacture. In the examples shown in FIG. 2P, seed layer 133s can be provided on outer passivation structure 123 and second conductive pattern 132 (e.g., pads 132p). In some examples, seed layer 133s can cover an exposed portion of second conductive pattern 132 (e.g., pads 132p). In some examples, the top side of second conductive pattern 132 (e.g., pads 132p) can be contacted by seed layer 133s. The process shown in FIG. 2P can be similar to or the same as the process shown in FIG. 2L.

FIG. 2Q shows cross-sectional view of electronic component 10 at a later stage of manufacture. In the examples shown in FIG. 2Q, a photoresist 159 can be coated on seed layer 133s located on outer passivation structure 123 and photoresist 159 can be patterned through an exposure, development, etch, and cure process to expose portions of seed layer 132s corresponding to (e.g., vertically overlapping) pads 132p of the uppermost second conductive pattern 132. In some examples, a width or diameter of the openings in photoresist 159 can be greater than the width or diameter of openings 1231 in outer passivation structure 123.

FIG. 2R shows cross-sectional view of electronic component 10 at a later stage of manufacture. In the examples shown in FIG. 2R, device interconnects 150 are provided over seed layer 133s and second conductive pattern 132. In some examples, device interconnect 150 can comprise contact pad 150a and terminal tip 150b. In some examples, contact pad 150a can be referred to as third conductive pattern 133 or outer conductive pattern 133. Contact pad 150a can be provided on seed layer 133s. In some examples, contact pad 150a can be provided on the portion of seed layer 133s exposed by photoresist 159. Contact pad 150a can comprise Cu, Ni, Pd, Ag, Au, or UBM. In some examples, the thickness of contact pad 150a can range from about 3 μm to about 500 μm. In some examples, terminal tip 150b can be electrolytically deposited on contact pad 150a. Terminal tip 150b can also be provided in the opening defined by photoresist 159. In some examples, terminal tip 150b can comprise Sn (tin), Ag (silver), Pb (lead), Cu (copper), Sn—Pb, Sn₃₇—Pb, Sn₉₅—Pb, Sn—Pb—Ag, Sn—Cu, Sn—Ag, Sn—Au, Sn—Bi, or Sn—Ag—Cu. In some examples, the diameter or width of terminal tip 150b can range from about 0.01 millimeter (mm) to about 10 mm. Terminal tip 150b can be configured to couple electronic component 10 to an external device.

FIG. 2S shows cross-sectional view of electronic component 10 at a later stage of manufacture. In the examples shown in FIG. 2S, photoresist 159 is removed. photoresist 159 can be removed by, for example, a liquid resist stripper. In some examples, the liquid resist stripper can comprise monoethanolamine and 2-butoxy ethanol. In some examples, photoresist 159 can be removed by an oxygen-containing plasma. In some examples, photoresist 159 can also be removed by a 1-methyl-2-pyrrolidone (NMP) solvent. In some examples, once photoresist 159 is dissolved, the solvent can be removed by heating to about 80° C. so no residue is left. In accordance with various examples, the top side and lateral sides of device interconnect 150 including contact pad 150a and terminal tip 150b can be exposed.

In some examples, device interconnects 150 can be used as a mask, and the portions of seed layer 133s outside the footprints of device interconnects 150 can be removed. Seed layer 133s can be removed by a wet or dry etching process. In response to removal of seed layer 133s, the top side of outer passivation structure 123 outside device interconnects 150 can be exposed and the ends of seed layer 133s can be exposed and coplanar with the lateral sides of device interconnect 150.

FIG. 2T shows cross-sectional view of electronic component 10 at a later stage of manufacture. In the examples shown in FIG. 2T, terminal tip 150b of device interconnects 150 can be made generally semispherical by a reflow process or laser assisted process. In some examples, these processes can include temperatures of about 150° C. to about 250° C. suitable to reflow terminal tip 150b. As used herein with reference to temperatures, the term about can mean +/−5 degrees, +/−10 degrees, +/−15 degrees, +/−20 degrees, +/−25 degrees, for example.

In accordance with various examples, build-up RDL 12 including dielectric structure 120, conductive structure 130, and device interconnects 150 on substrate 11 can thus be formed. In some examples, build-up RDL 12 can comprise or be referred to as an RDL substrate. Build-up RDL 12 can include embedded traces with heterogeneous passivation structures. For example, first and second conductive patterns 131, 132 can be formed on and/or in high resolution second dielectric material 121b, 122b, and high function first dielectric material 121a, 122a can be located above and below first and second conductive patterns 131, 132 (e.g., below pads 131p, 132p and above and below traces 131t, 132t). High resolution second dielectric material 122b can allow for formation of narrow or fine pitch traces and vias, while high function first dielectric material 122a inhibits or prevents electrical noise, oxidation, and ion migration between the adjacent conductive elements.

In accordance with various examples, individual electronic components 10 can be provided by a singulation process. In some examples, the singulation process can include sawing or cutting through substrate 11, dielectric structure 120, and/or conductive structure 130 using, for example, diamond blade wheels or laser beams. In some examples, in response to singulation, lateral sides of substrate 11, dielectric structure 120, or conductive structure 130 can be coplanar.

In examples where substrate 11 is a removable carrier, substrate 11 can be separated from build-up RDL 12. In some examples, a wafer support system can be attached to build-up RDL 12 (e.g., over the top side of outer passivation structure 123 and device interconnects 150), and substrate 11 can then be removed from the opposite side of build-up RDL 12. In some examples, a temporary bond layer (e.g., a temporary bonding film, a temporary bonding tape, or a temporary adhesive coating) can be interposed between build-up RDL 12 and substrate 11. For example, the temporary bond layer can be a heat release tape (film) or an optical release tape (film), in which the adhesive strength is weakened or removed by heat or light, respectively. The temporary bond layer can allow build-up RDL 12 to be separated from substrate 11. In some examples, a force (e.g., chemical or physical) can also be used to overcome the adhesive strength of the temporary bond layer. In some examples, substrate 11 can be removed by mechanical grinding and chemical etching.

In response to removing or separating substrate 11 from build-up RDL 12, the bottom side of build-up RDL 12 can be exposed (e.g., the bottom sides of first dielectric material 121a and seed layer 131s can be exposed). In some examples, the bottom side of seed layer 131s and the bottom side of first dielectric material 121a can be coplanar. In some examples, the exposed (or bottom) portions of first conductive pattern 131 can comprise or be referred to as internal terminals.

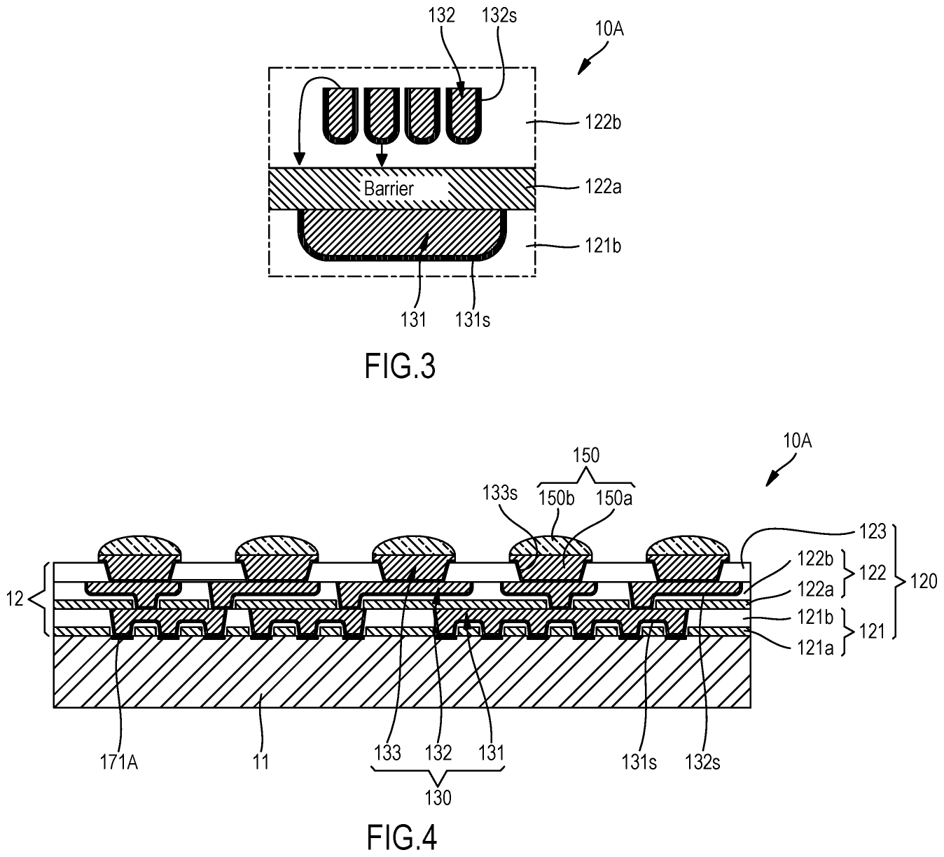

FIG. 3 shows a cross-sectional view of a portion of an example electronic component 10. In the examples shown in FIG. 3, first conductive pattern 131, with the bottom and lateral sides surrounded by seed layer 131s, can be embedded in second dielectric material 121b (e.g., high-resolution PI). Second conductive pattern 132, with the bottom and lateral sides surrounded by seed layer 132s, can be embedded in the second dielectric material 122b (e.g., high resolution PI). First dielectric material 122a (e.g., high-functional PI) can be interposed between first conductive pattern 131 and the second conductive pattern 132 and between dielectric material 121b and dielectric material 122b. A portion of second dielectric material 122b can also be located between second conductive pattern 132 and dielectric material 121b. Locating high functional first dielectric material 122a between first conductive pattern 131 and second conductive pattern 132 tends to inhibit migration of ions between first conductive pattern 131 and second conductive pattern 132, while second dielectric material 122b allows second conductive pattern 132 to be formed with narrow pitch traces and vias. First dielectric material 122a can reduce or prevent oxidation or formation of voids in first conductive pattern 131 and second conductive pattern 132. First dielectric material 122a also can inhibit or prevent electrical noise between first conductive pattern 131 and second conductive pattern 132.

FIG. 4 shows a cross-sectional view of an example electronic device 10A. In the example shown in FIG. 4, electronic device 10A can comprise substrate 11 and build-up RDL 12. Build-up RDL 12 can comprise dielectric structure 120 and conductive structure 130. In some examples, build-up RDL 12 can also comprise device interconnects 150. Dielectric structure 120 can include first passivation structure 121, having first dielectric material 121a and second dielectric material 121b, second passivation structure 122, having first dielectric material 122a and second dielectric material 122b, and outer passivation structure 123. Conductive structure 130 can include first conductive pattern 131, second conductive pattern 132, and outer conductive pattern 133.

In accordance with various examples, electronic device 10A can be manufactured using a process similar to or the same as the process shown in FIGS. 2A to 2T and described above. In some examples, electronic device 10A can comprise or be referred to as WLP or WLCSP. In some examples, substrate 11 of electronic device 10A can comprise or be referred to as a semiconductor die, a semiconductor chip, or a semiconductor package. In some examples, the die or chip can comprise an integrated circuit die separated from a semiconductor wafer having multiple die. In some examples, substrate 11 can comprise a DSP (digital signal processor), a network processor, a power management unit, an audio processor, a RF (radio-frequency) circuit, a wireless baseband SoC (system-on-chip) processor, a sensor, or an ASIC (application specific integrated circuit). Substrate 11 can perform calculation and control processing, store data, or remove noise from electrical signals. The conductive pattern 131 of conductive structure 130 can be coupled to I/O terminals (e.g., component interconnects 171A) of substrate 11.

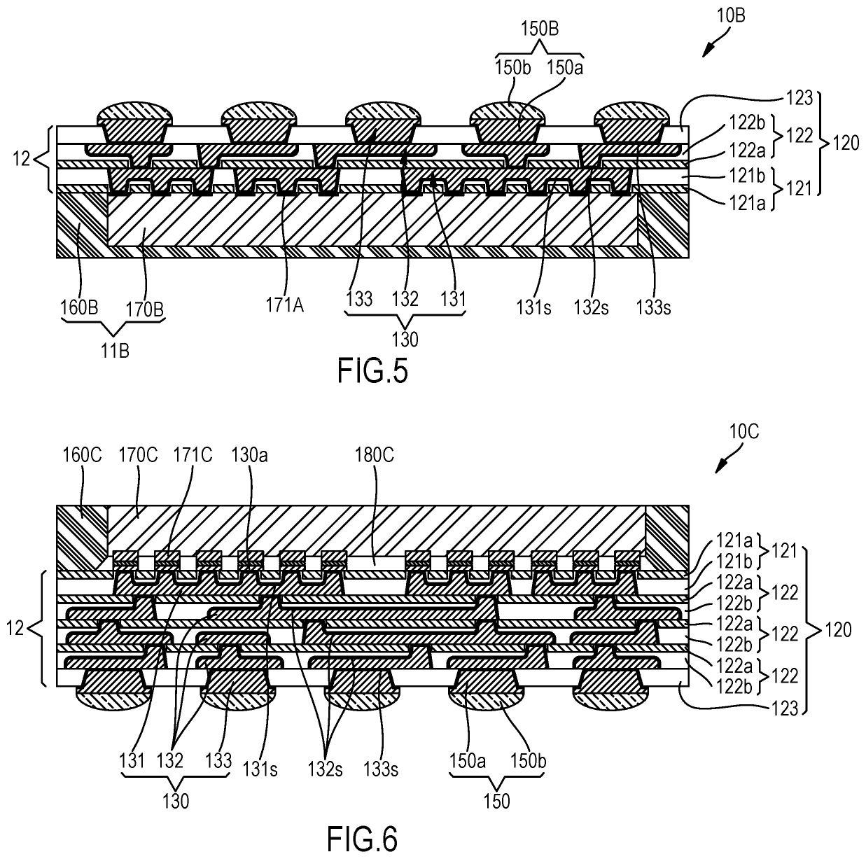

FIG. 5 shows a cross-sectional view of an example electronic device 10B. In the example shown in FIG. 5, electronic device 10B comprises substrate 11B and build-up RLD 12. Substrate 11B can comprise a reconstituted wafer. For example, substrate 11B can include electronic component 170B and encapsulant 160B. In some examples, electronic device 10B can comprise or be referred to as a WLFO. In some examples, electronic component 170B of electronic device 10B can comprise or be referred to as a semiconductor die, a semiconductor chip, or a semiconductor package. In some examples, electronic component 170B can comprise a DSP, network processor, power management unit, audio processor, RF circuit, wireless baseband SoC processor, sensor, or ASIC. Electronic component 170B can perform calculation and control processing, store data, or remove noise from electrical signals. The conductive pattern 131 of conductive structure 130 can be coupled to I/O terminals (e.g., component interconnects 171A) of electronic component 170B.

Build-up RDL 12 can comprise dielectric structure 120 and conductive structure 130. In some examples, build-up RDL 12 can also comprise device interconnects 150. Dielectric structure 120 can include first passivation structure 121, having first dielectric material 121a and second dielectric material 121b, second passivation structure 122, having first dielectric material 122a and second dielectric material 122b, and outer passivation structure 123. Conductive structure 130 can include first conductive pattern 131, second conductive pattern 132, and outer conductive pattern 133.

In accordance with various examples, electronic device 10B in FIG. 5 can be similar to electronic device 10A in FIG. 4 with electronic device 10B comprising encapsulant 160B. In some examples, electronic device 10B can be fabricated by a process similar to or the same as processes shown in FIGS. 2A-2T, with the process of FIGS. 2A-2T occurring over substrate 11B (e.g., over encapsulated electronic components 170B).

In some examples, encapsulant 160B can comprise an epoxy resin or a phenol resin, carbon black, and a silica filler. In some examples, encapsulant 160B can comprise or be referred to as a mold compound, a resin, a sealant, a filler-reinforced polymer, or an organic body. In some examples, encapsulant 160B can contact or cover a bottom side or lateral sides of electronic component 170B. In some examples, a bottom side of encapsulant 160B can be lower than the bottom side of electronic component 170B. In some examples, the bottom side of encapsulant 160B and the bottom side of electronic component 170B can be coplanar and the bottom side of electronic component 170B can be exposed from the bottom side of encapsulant 160B.

Encapsulant 160B can be provided by transfer molding, compression molding, liquid encapsulant molding, vacuum lamination, paste printing, film assist molding, or any other suitable deposition process. The thickness of encapsulant 160B can range from about 100 μm to about 2000 μm. Encapsulant 160B can protect electronic component 170B from external environment or environmental exposure and can dissipate heat from electronic component 170B.

In accordance with various examples, build-up RDL 12, including conductive structure 130 and dielectric structure 120, can be provided over the top side of encapsulant 160B as well as over the top side of electronic component 170B. In some examples, the process shown in FIGS. 2A-2T can be implemented on the top side of electronic component 170B and the top side of encapsulant 160B. In some examples, the top side of electronic component 170B and the top side of encapsulant 160B can be coplanar. In some examples, one or more of the device interconnects 150 or portions of conductive structure 130 can be located vertically over the top side of encapsulant 150B. In some examples, first passivation structure 121 (e.g., first dielectric material 121a) can contact encapsulant 160B. Conductive pattern 131 of conductive structure 130 can provide internal terminals of build-up RDL 12 (i.e., terminals opposite device interconnects 150), and can be coupled to I/O terminals (e.g., component interconnects 171A) of electronic component 170B.

In accordance with various examples, individual electronic devices 10B can be provided by a singulation process. In some examples, singulation can include sawing or cutting through encapsulant 160B and build-up RDL 12. In some examples, lateral sides of encapsulant 160B, dielectric structure 120, and/or conductive structure 130 can be coplanar.

FIG. 6 shows a cross-sectional view of an example electronic device 10C. In the example shown in FIG. 6, electronic device 10C can comprise electronic component 170C, build-up RDL 12, encapsulant 160C, and underfill 180C. Build-up RDL 12 can comprise dielectric structure 120 and conductive structure 130. In some examples, build-up RDL 12 can also comprise device interconnects 150. Dielectric structure 120 can include first passivation structure 121, having first dielectric material 121a and second dielectric material 121b, second passivation structure 122, having first dielectric material 122a and second dielectric material 122b, and outer passivation structure 123. Conductive structure 130 can include first conductive pattern 131, second conductive pattern 132, and outer conductive pattern 133. Build-up RDL 12 can be formed, as previously described with reference to FIGS. 2A-2T. Electronic device 10C in FIG. 6 can be similar to electronic device 10B shown in FIG. 5, but with build-up RDL 12 provided prior to coupling electronic component 170C to build-up RDL 12.

In accordance with various examples, substrate 11 (FIG. 2T) can be removed from build-up RDL 12 after the process shown in FIG. 2T. In some examples, build-up RDL 12 can be turned over (i.e., rotated 180°) and electronic component 170C can be attached to the internal terminals 130a of build-up RDL 12. In accordance with various examples, the exposed portions of first conductive pattern 131, which can include seed layer 131s, can provide or be referred to as internal terminals 130a of build-up RDL 12. In some examples, electronic component 170C can comprise or be referred to as a die, chip, package, or passive element. In some examples, the thickness of electronic component 170C can range from about 20 μm to about 1000 μm.

In accordance with various examples, component interconnects 171C of electronic component 170C can be coupled to internal terminals 130a of build-up RDL 12. In some examples, component interconnect 171C can comprise or be referred to as a bump, pad, or pillar. In some examples, the thickness of component interconnect 171C can range from about 1 μm to about 10 μm. In some examples, component interconnects 171C can be coupled to or contact seed layer 131s. In some examples, component interconnects 171C can be coupled to internal terminals 130a via solder. In some examples, component interconnects 171C can be coupled to internal terminal 130a by a thermocompression bonding process, an ultrasonic bonding process, a laser assisted bonding process, or a hybrid bonding process. In some examples, a conductive structure, such as a UBM or bond pad, can be formed over internal terminals 130a after removal of the substrate 11, and component interconnects 171C can be coupled to or contact said conductive structure.

Underfill 180C can be provided between build-up RDL 12 and electronic component 170C. In some examples, underfill 180C can contact build-up RDL 12 (e.g., dielectric structure 120 or conductive structure 130), component interconnects 171C, or electronic component 170C. In some examples, underfill 180C can comprise or be referred to as CUF (capillary underfill), NCP (non-conductive pasted), NCF (non-conductive film), or ACF (anisotropic conductive film). In some examples, underfill 180C can be inserted into a gap between electronic component 170C and build-up RDL 12 after electronic component 170C is coupled to build-up RDL 12. In some examples, underfill 180C can be pre-coated onto build-up RDL 12 prior to electronic component 170C being coupled to build-up RDL 12. In some examples, underfill 180C can be pre-coated on electronic component 170C prior to electronic component 170C being coupled to build-up RDL 12. In some examples, a curing process (for example, a thermal curing process or a photocuring process) of underfill 180C can be performed.

In some examples, encapsulant 160C can be disposed over build-up RDL 12, electronic component 170C, and underfill 180C. Encapsulant 160C can cover build-up RDL 12, electronic component 170C, and underfill 180C. In some examples, encapsulant 160C can contact build-up RDL 12, electronic component 170C, and underfill 180C. In some examples, underfill 180C can be omitted, and encapsulant 160C can be filled between electronic component 170C and build-up RDL 12. In some examples, encapsulant 160C can be located over a top side of electronic component 170C. In some examples, encapsulant 160C can be coplanar with the top side of electronic component 170C.

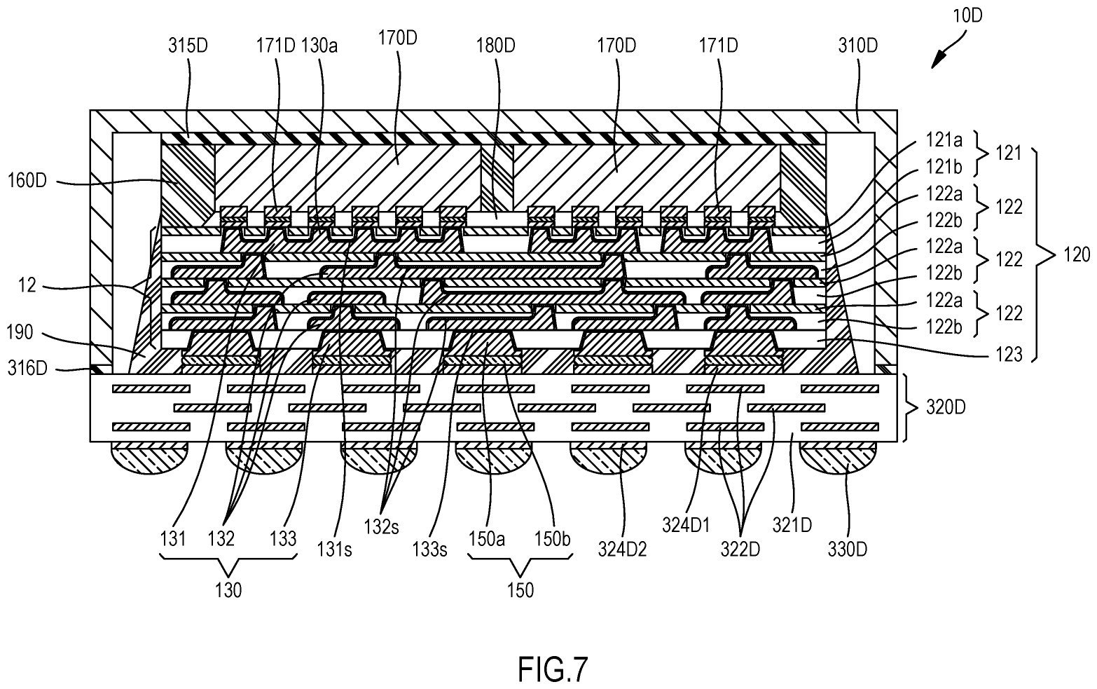

FIG. 7 shows a cross-sectional view of an example electronic device 10D. In the example shown in FIG. 7, electronic device 10D can comprise one or more electronic component(s) 170D, component interconnects 171D, build-up RDL 12, encapsulant 160D, underfill 180D, base substrate 320D, external interconnects 330D, underfill 190, lid 310D, and interface materials 315D and 316D. Build-up RDL 12 includes dielectric structure 120, conductive structure 130, and device interconnects 150, as previously described with respect to FIGS. 2A-2T. In the example shown in FIG. 7, electronic device 10D can be formed by providing build-up RDL 12 prior to coupling electronic components 170D to build-up RDL 12.

In accordance with various examples, base substrate 320D can comprise dielectric structure 321D and conductive structure 322D. In some examples, dielectric structure 321D can comprise one or more layers of dielectric materials interleaved with the layers of conductive structure 322D. In some examples, the dielectric materials can comprise PI, BCB, PBO, resin, or ABF. In some examples, conductive structure 322D can comprise one or more conductive layers defining signal distribution elements (e.g., traces, vias, pads, conductive paths, or UBM). Conductive structure 322D can comprise substrate inward terminals 324D1 and substrate outward terminals 324D2. In some examples, substrate inward terminals 324D1 can comprise pads, lands, UBM, or studs. In some examples, substrate outward terminals 324D2 can comprise pads, lands, or UBM. External interconnects 330D can comprise solder balls, bumps, pads, pillars, solder coated copper core balls, or solder capped copper pillars. External interconnects 330D can be coupled to substrate outward terminal 324D2 of base substrate 320D. In some examples, outward terminal 324D2 can comprise an LGA (land grid array).

In some examples, base substrate 320D can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers, can be attached as a pre-formed film rather than as a liquid, and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate omitting the permanent core structure, and the dielectric and conductive layers can be formed on a sacrificial carrier and removed after formation of the dielectric and conductive layers and before attachment to the electronic device. The pre-formed substrate can be referred to as a printed circuit board (PCB) or a laminate substrate. Such pre-formed substrates can be formed through semi-additive or modified-semi-additive processes.

In some examples, base substrate 320D can be an RDL substrate. RDL substrates can comprise one or more conductive layers and one or more dielectric layers and (a) can be formed layer by layer over an electronic device to which the RDL substrate is electrically coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through which light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction in the vertical thickness or height of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), or silicon oxynitride (SiON). The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as coreless substrates.

Device interconnects 150 of build-up RDL 12 can be coupled to substrate inward terminals 324D1 of base substrate 320D. In some examples, device interconnects 150 can be coupled to inward terminal 324D1 by thermal compression bonding, ultrasonic bonding, laser assisted bonding, or hybrid bonding. In some examples, solder can be interposed between device interconnects 150 and inward terminals 324D1. In some examples, underfill 190 can be interposed between build-up RDL 12 and base substrate 320D. In some examples, underfill 190 can be located over or can cover the lateral sides of build-up RDL 12.

In some examples, lid 310D can be coupled to electronic components 170D via interface material 315D. Lid 310D can be coupled to base substrate 320D via interface material 316D. In some examples, lid 310D can comprise a heat spreader and can be coupled (e.g., thermally and/or mechanically) to electronic components 170D via a thermally conductive interface material 315D. For example, interface material 315D can comprise a thermal interface material (TIM). In some examples, interface material 315D can also be interposed between encapsulant 160D and lid 310D. Lid 310D can comprise or be referred to as a cover, case, or housing. In some examples, lid 310D can provide electromagnetic interference (EMI) shielding. The height of lid 310D can range from about 100 μm to about 1000 μm. Interface material 316D can couple lid 310D to the upper side of base substrate 320D. Interface material 316D can comprise, for example, an adhesive. In some examples, interface material 316D can be electrically insulating. In some examples, interface material 316D can be electrically conductive and can couple lid 310D to conductive structure 322D of base substrate 320D. In some examples, lid 310D can be conformally applied (e.g., comprise a conformal coating applied) over the top and/or lateral sides of electronic components 170D, encapsulant 160D, build-up RDL 12, underfill 190 and/or base substrate 320D. Lid 310D can dissipate heat from electronic components 170D and/or can protect build-up RDL 12 and electronic components 170D from the external environment.

A heterogeneous, multi-passivation structure can include a high-functional dielectric and a high-resolution dielectric. The high-functional dielectric can be disposed between adjacent conductive elements (e.g., traces or other conductive structures in high-resolution material) of an electronic device. The high-functional dielectric tends to inhibit electrical noise, oxidation, and ion migration between the adjacent conductive elements. Embedded traces, for example, can be formed in the high-resolution dielectric material of a heterogeneous passivation structure. The high-functional insulating material and high-resolution insulating material can be interleaved, layered, selectively placed, or otherwise selectively located in a heterogeneous passivation structure to increase reliability and electrical performance of fine-pitch traces or other conductive elements.

The present disclosure includes reference to certain examples. However, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate;
a first passivation structure over the substrate and defining a first opening;
a first conductive pattern formed in the first opening;
a second passivation structure over the first conductive pattern and the first passivation structure, wherein the second passivation structure comprises a high-resolution material and a high-function material, wherein the high-resolution material of the second passivation structure defines a second opening; and
a second conductive pattern disposed in the second opening of the second passivation structure, wherein the high-function material is disposed between the first conductive pattern and the second conductive pattern.

2. The electronic device of claim 1, wherein the high-function material defines a first via extending through the second passivation structure to the first conductive pattern, wherein the high-resolution material defines a second via extending through the first via of the second passivation structure to the first conductive pattern.

3. The electronic device of claim 2, further comprising a seed layer extending through the first via and the second via to the first conductive pattern, wherein the high-resolution material is between the high-function material and the seed layer.

4. The electronic device of claim 1, wherein the high-function material comprises a dielectric constant (Dk) less than 3.0.

5. The electronic device of claim 1, wherein the high-function material comprises a dissipation factor (Df) less than 0.004.

6. The electronic device of claim 1, wherein the high-resolution material comprises a material capable of patterning at a resolution value less than 2 micrometers.

7. The electronic device of claim 1, wherein the high-function material comprises a first organic and the high-resolution material comprises a second organic.

8. The electronic device of claim 1, wherein the substrate comprises:
an electronic component; and
an encapsulant disposed around lateral sides of the electronic component.

9. The electronic device of claim 8, further comprising:
a thermal adhesive coupled to a top side of the electronic component; and
a heat spreader coupled to the thermal adhesive.

10. The electronic device of claim 9, further comprising a base substrate electrically coupled to the electronic component through the first conductive pattern and the second conductive pattern, wherein the heat spreader is coupled to the base substrate.

11. The electronic device of claim 8, further comprising an underfill disposed between the electronic component and the first passivation structure.

12. The electronic device of claim 1, wherein the high-resolution material comprises a positive-type photo-sensitive polyimide (PSPI).

13. An electronic device, comprising:
a substrate;
a first dielectric material over the substrate and defining a first opening;
a first conductive pattern formed in the first opening;
a second dielectric material disposed over the first conductive pattern and the first dielectric material, wherein the second dielectric material comprises a high-function material that defines a second opening;
a third dielectric material disposed over the second dielectric material and extending into the second opening, wherein the third dielectric material comprises a high-resolution material that defines a third opening; and
a second conductive pattern disposed in the third opening of the high-resolution material, wherein the high-function material is disposed between the first conductive pattern and the second conductive pattern.

14. The electronic device of claim 13, wherein the high-function material defines a first via extending through the second dielectric material to the first conductive pattern, wherein the high-resolution material defines a second via extending through the first via to the first conductive pattern.

15. The electronic device of claim 13, wherein the high-function material comprises a dielectric constant (Dk) less than 3.0.

16. The electronic device of claim 13, wherein the high-function material comprises a dissipation factor (Df) less than 0.004.

17. The electronic device of claim 13, wherein the high-resolution material comprises a material capable of patterning at a resolution value less than or equal to 2 micrometers.

18. A method of manufacturing a semiconductor device, comprising:
providing a substrate;
providing a first dielectric material over the substrate, wherein the first dielectric material defines a first opening;
providing a first conductive pattern in the first opening;
providing a second dielectric material over the first conductive pattern and the first dielectric material, wherein the second dielectric material comprises a high-function material and defines a second opening;
providing a third dielectric material over the second dielectric material and extending into the second opening, wherein the third dielectric material comprises a high-resolution material and defines a third opening; and
providing a second conductive pattern disposed in the third opening of the third dielectric material, wherein the high-function material is disposed between the first conductive pattern and the second conductive pattern.

19. The method of claim 18, wherein the high-function material comprises a dielectric constant (Dk) less than 3.0 and a dissipation factor (Df) less than 0.004.

20. The method of claim 18, wherein the high-resolution material comprises a material capable of patterning at a resolution value less than or equal to 2 micrometers.
